(19) United States
(12) Patent Application Publication
(10) Pub. No.: US 2012/0044444 A1
(43) Pub. Date: Feb. 23, 2012

(54) SENSOR ARRAY SUBSTRATE, DISPLAY DEVICE INCLUDING THE SAME, AND METHOD OF MANUFACTURING THE SENSOR ARRAY SUBSTRATE

(75) Inventors: Kyung-Ho PARK, Cheonan-si (KR); Soo-Hyun KIM, Chungju-si (KR)

(73) Assignee: SAMSUNG ELECTRONICS CO., LTD., Suwon-si (KR)

(21) Appl. No.: 13/070,260

(22) Filed: Mar. 23, 2011

(30) Foreign Application Priority Data
Aug. 20, 2010 (KR) 10-2010-0080910

(51) Int. Cl. G02F 1/1333; H01L 31/18; H01L 27/146; H01L 31/0232

(52) U.S. Cl. 349/106; 257/432; 438/70; 257/443; 349/122; 257/E31.127; 257/E31.001; 257/E27.13

(57) ABSTRACT

Provided are a sensor array substrate, a display device including the same, and a method of manufacturing the sensor array substrate. The sensor array substrate includes: a substrate; a plurality of pixel regions defined by intersections of gate wirings and data wirings on the substrate; and a plurality of first sensor units and a plurality of second sensor units which are formed in the pixel regions. The first sensor units sense light in an infrared wavelength range, the second sensor units sense light in a visible wavelength range, two first sensor units that are disposed adjacent to each other in a data wiring direction form a first group, and two second sensor units that are disposed adjacent to each other in the data wiring direction form a second group. The first and second groups are alternately arranged in the data wiring direction and a gate wiring direction.

This application claims priority from and the benefit of Korean Patent Application No. 10-2010-0080910, filed on Aug. 20, 2010, which is hereby incorporated by reference for all purposes as if fully set forth herein.

### BACKGROUND OF THE INVENTION

1. Field of the Invention

Exemplary embodiments of the present invention relate to a sensor array substrate, a display device including the same, and a method of manufacturing the same.

2. Discussion of the Background

Display devices including a sensor array substrate can be touched with a finger or pen to input data. According to their operating principles, display devices including a sensor array substrate are classified into resistive display devices, capacitive display devices, optical sensor display devices, and the like.

Resistive display devices operate by sensing contact between electrodes that occurs when a pressure exceeding a predetermined level is applied onto the electrodes. Capacitive display devices operate by sensing a change in capacitance that results from the touch of a finger.

### SUMMARY OF THE INVENTION

Exemplary embodiments of the present invention provide a display device including a sensor array substrate that can be used with both a progressive scan method and an interlaced scan method.

Exemplary embodiments of the present invention also provide a sensor array substrate that can be used with both a progressive scan method and an interlaced scan method, according to the arrangement of the sensors.

Exemplary embodiments of the present invention also provide a display device having sensors arranged such that both the progressive scan method and the interlaced scan method can be applied to the display device.

Exemplary embodiments of the present invention also provide a method of manufacturing a sensor array substrate having sensors arranged such that both the progressive scan method and the interlaced scan method can be applied to the sensor array substrate.

Additional features of the invention will be set forth in the description which follows, and in part will be apparent from the description, or may be learned by practice of the invention.

An exemplary embodiment of the present invention discloses a sensor array substrate including: a substrate; a plurality of pixel regions defined by intersections of gate wirings and data wirings on the substrate; and a plurality of first sensor units and a plurality of second sensor units disposed in the pixel regions. The first sensor units are configured to sense light in an infrared wavelength range, the second sensor units are configured to sense light in a visible wavelength range, two first sensor units disposed adjacent to each other in a data wiring direction form a first group, and two second sensor units disposed adjacent to each other in the data wiring direction form a second group. The first and second groups are alternately arranged in the data wiring direction and in a gate wiring direction.

An exemplary embodiment of the present invention also discloses a display device including: a sensor array substrate; a display substrate facing the sensor array substrate and including pixel electrodes; and a liquid crystal layer interposed between the sensor array substrate and the display substrate. The sensor array substrate includes: a substrate; a plurality of pixel regions defined by intersections of gate wirings and data wirings on the substrate; a plurality of first sensor units disposed in first pixel regions and configured to sense light in an infrared wavelength range; and a plurality of second sensor units disposed in second pixel regions and configured to sense light in a visible wavelength range. Two first sensor units which adjacent to each other in a data wiring direction form a first group, and two second sensor units disposed adjacent to each other in the data wiring direction form a second group. The first and second groups are alternately arranged in the data wiring direction and in a gate wiring direction.

An exemplary embodiment of the present invention also discloses a method of manufacturing a sensor array substrate. The method includes forming gate wirings and data wirings, which define a plurality of pixel regions, on a substrate; and forming a plurality of first sensor units and a plurality of second sensor units in the pixel regions. The first sensor units are configured to sense light in an infrared wavelength range, the second sensor units are configured to sense light in a visible wavelength range, two first sensor units disposed adjacent to each other in a data wiring direction form a first group, and two second sensor units disposed adjacent to each other in the data wiring direction form a second group. The first and second groups are alternately arranged in the data wiring direction and in a gate wiring direction.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a cross-sectional view of a sensor array substrate according to a first exemplary embodiment of the present invention.

FIG. 2 is a diagram illustrating the arrangement of first and second sensor units according to the first exemplary embodiment of the present invention.

FIG. 3 is a schematic diagram of the arrangement of FIG. 2.

FIG. 4 and FIG. 5 are diagrams respectively illustrating the principles of driving the first and second sensor units arranged as shown in FIG. 2 by using different scan methods.

FIG. 6 is a cross-sectional view of a display device according to the first exemplary embodiment of the present invention.

FIG. 7 is a flowchart illustrating a method of manufacturing the sensor array substrate according to the first exemplary embodiment of the present invention.

FIG. 8, FIG. 9, FIG. 10, FIG. 11, FIG. 12, FIG. 13, and FIG. 14 are cross-sectional views for sequentially explaining processes included in the method of manufacturing the sensor array substrate according to the first exemplary embodiment of the present invention.

FIG. 15 is a cross-sectional view of a sensor array substrate according to a second exemplary embodiment of the present invention.

FIG. 16 is a cross-sectional view of a display device according to the second exemplary embodiment of the present invention.

FIG. 17 is a flowchart illustrating a method of manufacturing the sensor array substrate according to the second exemplary embodiment of the present invention.

FIG. 18 is a cross-sectional view for explaining processes included in the method of manufacturing the sensor array substrate according to the second exemplary embodiment of the present invention.

FIG. 19 is a cross-sectional view of a sensor array substrate according to a third exemplary embodiment of the present invention.

FIG. 20 is a cross-sectional view of a display device according to the third exemplary embodiment of the present invention.

FIG. 21 is a flowchart illustrating a method of manufacturing the sensor array substrate according to the third exemplary embodiment of the present invention.

FIG. 22 is a cross-sectional view for explaining processes included in the method of manufacturing the sensor array substrate according to the third exemplary embodiment of the present invention.

### DETAILED DESCRIPTION OF THE ILLUSTRATED EMBODIMENTS

Advantages and features of the present invention and methods of accomplishing the same may be understood more readily by reference to the following detailed description of exemplary embodiments and the accompanying drawings. The present invention may, however, be embodied in many different forms and should not be construed as being limited to the exemplary embodiments set forth herein. Rather, these exemplary embodiments are provided so that this disclosure will be thorough and complete and will fully convey the concept of the invention to those skilled in the art, and the present invention will only be defined by the appended claims. In the drawings, sizes and relative sizes of layers and regions may be exaggerated for clarity.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present. Like reference numerals refer to like elements throughout the specification. As used herein, the term “and/or” includes any and all combinations of one or more of the associated listed items.

Spatially relative terms, such as “below”, “beneath”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation, in addition to the orientation depicted in the figures.

Exemplary embodiments of the invention are described herein with reference to plan and cross-section illustrations that are schematic illustrations of idealized exemplary embodiments of the invention. As such, variations from the shapes of the illustrations as a result, for example, of manufacturing techniques and/or tolerances, are to be expected. Thus, the exemplary embodiments of the invention should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the invention.

Hereinafter, a sensor array substrate, a display device including the same, and a method of manufacturing the sensor array substrate according to exemplary embodiments of the present invention will be described with reference to the attached drawings.

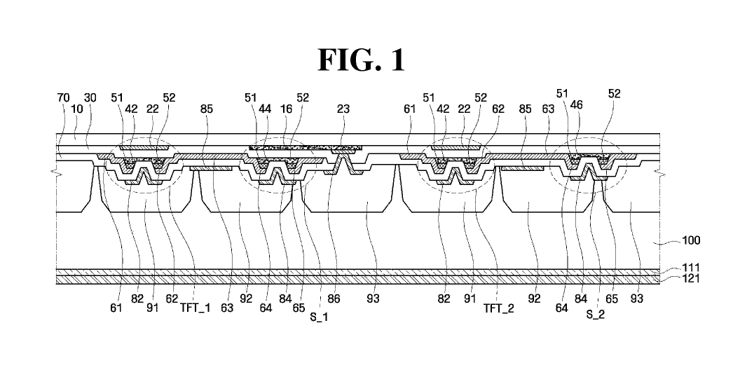

First, a sensor array substrate, a display device including the same, and a method of manufacturing the sensor array substrate according to a first exemplary embodiment of the present invention will be described with reference to FIGS. 1 through 14.

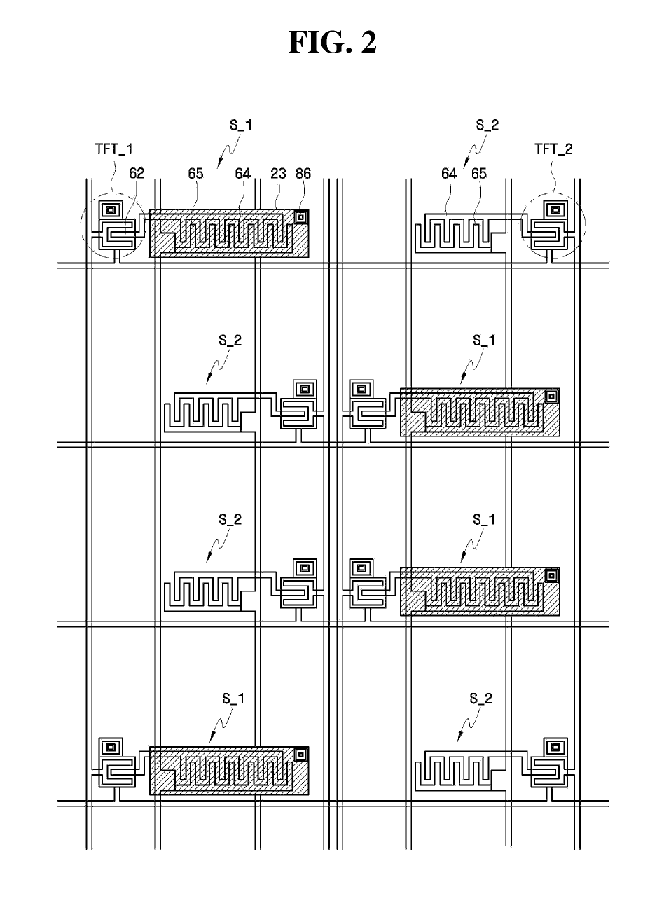

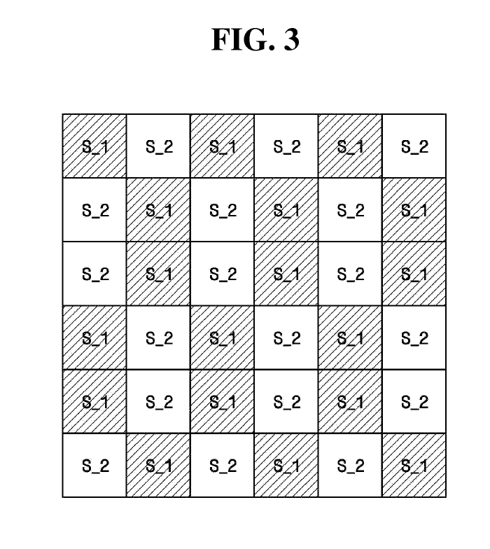

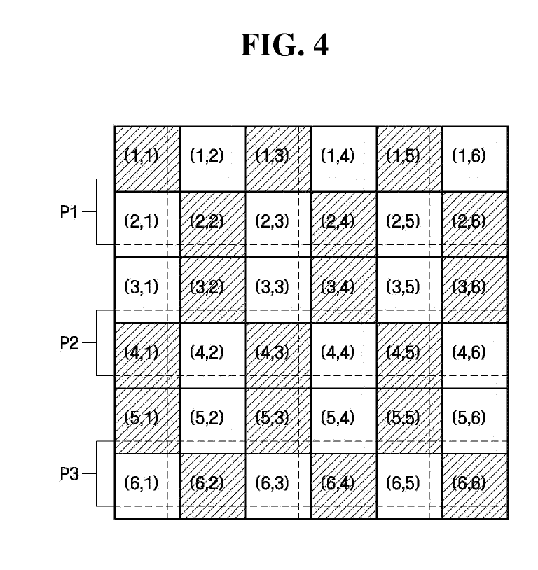

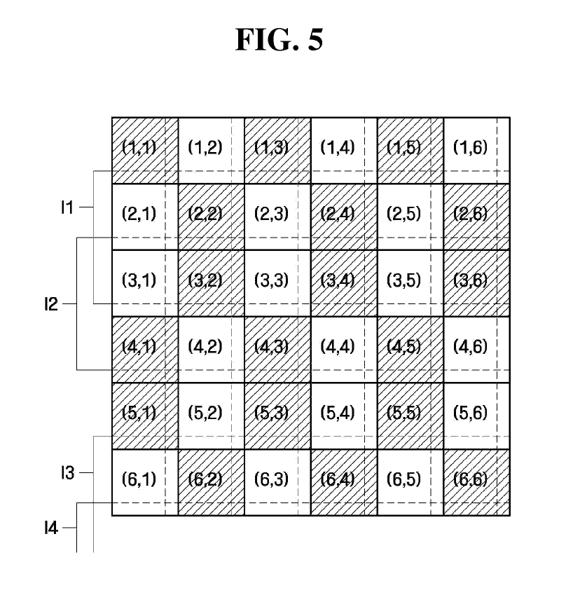

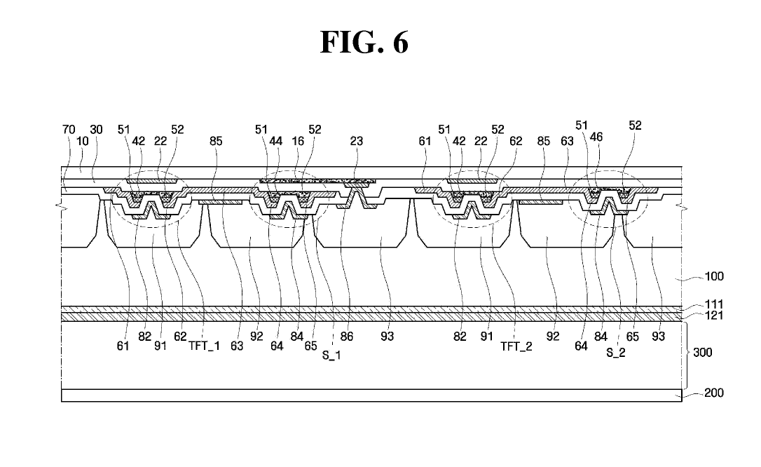

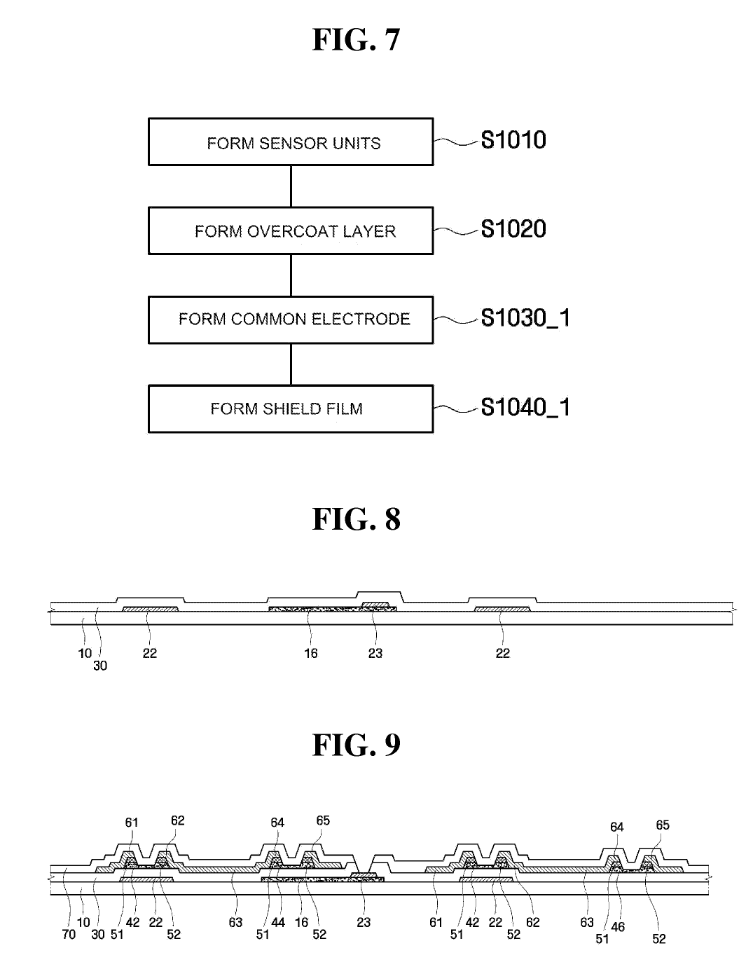

FIG. 1 is a cross-sectional view of a sensor array substrate according to a first exemplary embodiment of the present invention. FIG. 2 is a diagram illustrating the arrangement of first and second sensor units S_1 and S_2 according to the first exemplary embodiment of the present invention. FIG. 3 is a schematic diagram of the arrangement of FIG. 2. FIGS. 4 and 5 are diagrams respectively illustrating the principles of driving the first and second sensor units S_1 and S_2 arranged as shown in FIG. 2 by using different scan methods. FIG. 6 is a cross-sectional view of a display device according to the first exemplary embodiment of the present invention. FIG. 7 is a flowchart illustrating a method of manufacturing the sensor array substrate according to the first exemplary embodiment of the present invention. FIGS. 8 through 14 are cross-sectional views for sequentially explaining processes included in the method of manufacturing the sensor array substrate according to the first exemplary embodiment of the present invention.

Referring to FIG. 1, the sensor array substrate according to the first exemplary embodiment includes various elements such as the first and second sensor units S_1 and S_2 and first and second thin-film transistors TFT_1 and TFT_2, all of which are formed on a substrate 10.

The substrate 10 may be made of glass, such as soda lime glass or boro silicate glass, or plastic.

A light-blocking pattern 16 is formed on a region of the substrate 10 where each of the first sensor units S_1 is formed. The light-blocking pattern 16 prevents light in a visible wavelength range from entering a first sensor semiconductor layer 44 of each first sensor unit S_1 while allowing light in an infrared wavelength range to transmit therethrough.

To sense light in the infrared wavelength range, the first sensor semiconductor layer 44 of each of the first sensor units S_1 may contain a material having a small band gap. Here, if light in the visible wavelength range is incident on the first sensor semiconductor layer 44, the first sensor semiconductor layer 44 may sense the light in the visible wavelength range, thereby generating a signal. Accordingly, the first sensor units S_1 may malfunction. The light-blocking pattern 16 may be included to prevent this malfunction of the first sensor units S_1.

When light in the visible wavelength range is incident on the light-blocking pattern 16, the light-blocking pattern 16 may generate a signal due to a photovoltaic effect. Accordingly, the light in the visible wavelength range can be prevented from entering the first sensor semiconductor layer 44. The light-blocking pattern 16 may be made of a-Si or a-SiGe. In addition, the light-blocking pattern 16 may be made of a material having a relatively larger band gap than that of the material of the first sensor semiconductor layer 44. The light-blocking pattern 16 may be island-shaped and may overlap the first sensor semiconductor layer 44 to prevent light in the visible wavelength range from entering the first sensor semiconductor layer 44. Further, the boundary of the first sensor semiconductor layer 44 may be located within the boundary of the light-blocking pattern 16.

Gate wirings, which deliver gate signals, are formed on the substrate 10. Each gate wiring includes a gate line 21 that extends in a first direction, e.g., a horizontal direction, and a gate electrode 22 that protrudes from the gate line and is included in each of the first and second thin-film transistors TFT_1 and TFT_2.

A ground wiring 23 is formed on the substrate 10 and is electrically connected to the light-blocking pattern 16. When the light-blocking pattern 16 generates a voltage after absorbing visible light, the ground wiring 23 discharges the generated voltage to ground. Accordingly, the ground wiring 23 prevents the light-blocking pattern 16 from functioning as a gate electrode of each first sensor unit S_1. That is, when the light-blocking pattern 16 absorbs light in the visible wavelength range, it may generate a voltage due to the photovoltaic effect. In this case, the light-blocking pattern 16 may function as a gate electrode of each first sensor unit S_1, thereby causing the first sensor units S_1 to malfunction. However, including the ground wiring 23 can prevent the malfunction of the first sensor units S_1 caused by the light-blocking pattern 16. The ground wiring 23 may extend in the first direction, e.g., in the horizontal direction of the substrate 10 to be substantially parallel to the gate line.

The gate wirings (i.e., the gate line and the gate electrode 22) and the ground wiring 23 may be made of Al-based metal such as Al and an Al alloy, Ag-based metal such as Ag and an Ag alloy, Cu-based metal such as Cu and a Cu alloy, Mo-based metal such as Mo and a Mo alloy, Cr, Ti, or Ta.

In addition, the gate wirings and the ground wiring 23 may have a multi-film structure composed of two conductive films (not shown) with different physical characteristics. One of the two conductive films may be made of metal with low resistivity, such as Al-based metal, Ag-based metal or Cu-based metal, in order to reduce a signal delay or a voltage drop of the gate wirings and the ground wiring 23. The other one of the conductive films may be made of a different material, in particular, a material having superior contact characteristics with ZnO, indium tin oxide (ITO), and indium zinc oxide (IZO), such as Mo-based metal, Cr, Ti, or Ta. Examples of multi-film structures include a chrome lower film and an aluminum upper film and an aluminum lower film and a molybdenum upper film. Other variations are possible as the gate wirings and the ground wiring 23 may be made of various metals and conductors, and they may include more than two layers.

A gate insulating film 30, which may be made of SiOx or SiNx, is disposed on the substrate 10, the gate wirings (i.e., the gate line and the gate electrode 22), the ground wiring 23, and the light-blocking pattern 16.

A semiconductor layer 42 is disposed on gate insulating film 30 to overlap each gate electrode 22 and is made of a semiconductor such as hydrogenated amorphous silicon or polycrystalline silicon. The semiconductor layer 42 may be island-shaped.

Ohmic contact layer patterns 51 and 52 formed of a material, such as silicide or n+ hydrogenated amorphous silicon heavily doped with n-type impurities, are disposed on the semiconductor layer 42.

First and second sensor semiconductor layers 44 and 46 of the first and second sensor units S_1 and S_2, respectively, are formed on the gate insulating film 30 to sense light.

The first and second sensor semiconductor layers 44 and 46 may have a single-layer or multi-layer structure containing one or more of a-Si, a-SiGe, and mc-Si.

Specifically, when the first sensor units S_1 are configured to sense light in the infrared wavelength range, the first sensor semiconductor layer 44 may contain a-SiGe or mc-Si. When the second sensor units S_2 are configured to sense light in the visible wavelength range, the second sensor semiconductor layer 46 may contain a-Si or a-SiGe. Here, the band gap of the first sensor semiconductor layer 44 may be smaller than that of the second sensor semiconductor layer 46. Accordingly, the first sensor semiconductor layer 44 generates a signal by sensing light in the infrared wavelength range, and the second sensor semiconductor layer 46 generates a signal by sensing light in the visible wavelength range. The first sensor units S_1 and the second sensor units S_2 may be arranged on the substrate 10 in such a pattern that allows both a progressive scan method and an interlaced scan method to be applied to the sensor array substrate. This will be described in detail below.

The ohmic contact layer patterns 51 and 52 made of a material, such as silicide or n+ hydrogenated amorphous silicon heavily doped with n-type impurities, are disposed on each of the first and second sensor semiconductor layers 44 and 46.

Data wirings are formed on the ohmic contact layer patterns 51 and 52. Each data wiring includes a data line, a source electrode 61, a drain electrode 62, and a drain electrode extension portion 63. The data line extends in a second direction, e.g., a vertical direction, and intersects the gate line to define a pixel. The source electrode 61 branches from the data line and extends onto the semiconductor layer 42. The drain electrode 62 is separated from the source electrode 61, formed on the semiconductor layer 42, and faces the source electrode 61 with respect to the gate electrode 22 or a channel region of the semiconductor layer 42. The drain electrode extension portion 63 extends from the drain electrode 62 and is connected to a sensor source electrode 64.

As shown in FIG. 1, the data wirings may directly contact the ohmic contact layer patterns 51 and 52 to form an ohmic contact. Since the ohmic contact layer patterns 51 and 52 function as an ohmic contact, the data wirings may be a single layer made of a material having low resistance. For example, the data wirings may be made of Cu, Al, Ti, or Ag.

In order to improve ohmic contact characteristics, the data wirings (i.e., the data line, the source and drain electrodes 61 and 62, and the drain electrode extension portion 63) may have a single-film or multi-film structure composed of a material or materials selected from Ni, Co, Ti, Ag, Cu, Mo, Al, Be, Nb, Au, Fe, Se, and Ta. Examples of the multi-film structure include a double film, such as Ta/Al, Ni/Al, Co/Al, Mo (Mo alloy)/Cu, Mo(Mo alloy)/Cu, Ti(Ti alloy)/Cu, TiN(TiN alloy)/Cu, Ta(Ta alloy)/Cu, TiOx/Cu, Al/Nd or Mo/Nb, and a triple film such as Ti/Al/Ti, Ta/Al/Ta, Ti/Al/TiN, Ta/Al/TaN, Ni/Al/Ni or Co/Al/Co. Other variations are possible as the data wirings may be made of various metals and conductors, and they may include more than three layers.

Sensing wirings are formed on the gate insulating film 30 to be parallel to the data wirings. Each sensing wiring includes a sensing line (not shown), the sensor source electrode 64, and a sensor drain electrode 65. The sensing line of the sensor source electrode 64 extends parallel to the data line and is connected to the drain electrode 62 by the drain electrode extension portion 63. The sensor source electrode 64 is formed on each of the first and second sensor semiconductor layers 44 and 46. The sensor drain electrode 65 branches from the sensing line, extends onto each of the first and second sensor semiconductor layers 44 and 46, and faces the sensor source electrode 64.

The sensing wirings may directly contact the ohmic contact layer patterns 51 and 52 to form an ohmic contact. The structure and material of the sensing wirings may be the same as those of the above-described data wirings, and thus a redundant description thereof is omitted.

A passivation film 70 is formed on the semiconductor layer 42, the first and second sensor semiconductor layers 44 and 46, the data wirings (i.e., the data line, the source and drain electrodes 61 and 62, and the drain electrode extension portion 63), and the sensing wirings (i.e., the sensing line, the sensor source electrode 64, and the sensor drain electrode 65). The passivation film 70 may be formed of an inorganic material such as silicon nitride or silicon oxide, an organic material having photosensitivity and superior planarization characteristics, or a low-k dielectric material formed by plasma enhanced chemical vapor deposition (PECVD), such as a-Si:C:O or a-Si:O:F. The passivation film 70 may be composed of a lower inorganic film and an upper organic film in order to protect exposed portions of the semiconductor layer 42 and the first and second sensor semiconductor layers 44 and 46 while taking advantage of the superior characteristics of an organic film.

A sensor gate electrode 84 is formed on the passivation film 70 to overlap each of the first and second sensor semiconductor layers 44 and 46. The sensor gate electrode 84 applies a bias voltage to each of the first and second sensor units S_1 and S_2. In addition, the sensor gate electrode 84 prevents light, which is emitted from a backlight unit (not shown), from entering the first and second sensor semiconductor layers 44 and 46. The sensor gate electrode 84 may be made of the same material as the above-described gate wirings (i.e., the gate line and the gate electrode 22).

First and second light-blocking films 82 and 85 are formed on the passivation film 70. Here, the first light-blocking film 82 overlaps the semiconductor layer 42 of each of the first and second thin-film transistors TFT_1 and TFT_2. The second light-blocking film 85 overlaps the drain electrode extension portion 63. Light emitted from the backlight unit is prevented from entering the semiconductor layer 42 and the drain electrode extension portion 63 by the first and second light-blocking films 82 and 85. Accordingly, malfunction of the first and second thin-film transistors TFT_1 and TFT_2 and the first and second sensor units S_1 and S_2 can be prevented. The first and second light-blocking films 82 and 85 may be made of the same material as the above-described gate wirings.

A ground connection wiring 86 is formed on the passivation film 70. The ground connection wiring 86 is connected to the ground wiring 23 by a via hole formed in the gate insulating film 30 and the passivation film 70. The ground connection wiring 86 discharges a signal, which is generated by the light-blocking pattern 16, to ground. The ground connection wiring 86 may be made of the same material as the above-described gate wirings.

As described above, each of the first and second thin-film transistors TFT_1 and TFT_2 may include the gate electrode 22, the gate insulating film 30, the semiconductor layer 42, the ohmic contact layer patterns 51 and 52, the source and drain electrodes 61 and 62, the drain electrode extension portion 63, and the passivation film 70, which are sequentially formed on the substrate 10. When necessary, each of the first and second thin-film transistors TFT_1 and TFT_2 may further include the first and second light-blocking films 82 and 85.

Each of the first and second sensor units S_1 and S_2 may include the gate insulating film 30, the first or second sensor semiconductor layer 44 or 46, the sensor source electrode 64, the sensor drain electrode 65, the passivation film 70, and the sensor gate electrode 84, which are sequentially formed on the substrate 10. Here, each first sensor unit S_1 may further include the light-blocking pattern 16, the ground wiring 23, and the ground connection wiring 86.

Color filter layers 91, 92, and 93 are formed on the passivation film 70, the sensor gate electrode 84, the ground connection wiring 86, and the first and second light-blocking films 82 and 85. The color filter layers 91, 92, and 93 may cause light, which passes through each subpixel region (not shown), to show a color. That is, the color filter layers 91, 92, and 93 determine the color of light that passes through each subpixel region defined on a display substrate 200 (see FIG. 6) that faces the sensor array substrate and includes pixel electrodes. Here, each subpixel region may show any one of red (R), green (G), and blue (B).

Three subpixel regions constitute one unit pixel region. That is, a unit pixel region may be defined as a region in which the color filter layers 91, 92, and 93 are formed. Each first thin-film transistor TFT_1 and each first sensor unit S_1 formed in a unit pixel region are electrically connected to each other. That is, each pair of a first thin-film transistor TFT_1 and a first sensor unit S_1 is formed in three subpixel regions. Here, a unit pixel region in which a first thin-film transistor TFT_1 and a first sensor unit S_1 are formed is referred to as a first unit pixel region. Each second thin-film transistor TFT_2 and each second sensor unit S_2 are formed in a second unit pixel region and are electrically connected to each other. The second unit pixel region neighbors the first unit pixel region.

A specific pattern in which the first and second sensor units S_1 and S_2 are arranged according to the first exemplary embodiment will now be described in detail with reference to FIGS. 2 through 5.

Referring to FIG. 2, the first and second sensor units S_1 and S_2 formed on the substrate 10 are arranged such that different sensor units are alternately arranged along the gate lines, which extend in the horizontal direction, and such that different pairs of identical sensor units are alternately arranged along the data lines, which extend in the vertical direction. That is, the first and second sensor units S_1 and S_2 are alternately arranged along each gate line, which extends in the horizontal direction of the substrate 10. In addition, pairs of the first sensor units S_1 and pairs of the second sensor units S_2 are alternately arranged along each data line, which extends in the vertical direction of the substrate 10.

This arrangement pattern of the first and second sensor units S_1 and S_2 is schematically illustrated in FIG. 3 and is thus more apparent from FIG. 3. In FIG. 3, the horizontal-axis direction represents the gate lines, and the vertical-axis direction represents the data lines. The gate lines and the data lines intersect each other to define a plurality of pixel regions, and the first and second sensor units S_1 and S_2 are arranged in the pixel regions. As described above, the first and second sensor units S_1 and S_2 are alternately arranged along the horizontal direction, and pairs of the first sensor units S_1 and pairs of the second sensor units S_2 are alternately arranged along the vertical direction.

In the conventional art, the first and second sensor units S_1 and S_2 are alternately arranged in both the horizontal-axis direction and the vertical-axis direction. This arrangement pattern can be applied when a plurality of sensors units are operated using a progressive scan method. However, when a plurality of sensor units are operated using an interlaced scan method, it is difficult to obtain accurate position coordinates because the same type of sensor units (the first or second sensor units S_1 or S_2) transmit signals through a single data wiring. To solve this problem, in the sensor array substrate according to the first exemplary embodiment, the first and second sensor units S_1 and S_2 may be arranged in the pattern as shown in FIG. 3.

When the first and second sensor units S_1 and S_2 are arranged as shown in FIG. 3, both the progressive scan method and the interlaced scan method can be applied to the sensor array substrate according to the first exemplary embodiment of the present invention, which will now be described in greater detail with reference to FIGS. 4 and 5. As an ordinarily skilled artisan understands, the illustrations of FIGS. 3-5 are merely for explanation, and the sensor array substrate may include more than 6 rows of gate wirings and 6 columns of data wirings.

FIG. 4 is a diagram illustrating a case where the progressive scan method is applied to the sensor array substrate according to the first exemplary embodiment of the present invention. Referring to FIG. 4, a method (hG2D) of simultaneously driving two gate wirings is applied to the sensor array substrate according to the first exemplary embodiment. That is, in FIG. 4, the top two gate wirings P1 (first and second rows) are simultaneously operated, and then the next two gate wirings P2 (third and fourth rows) are simultaneously operated. Finally, the last two gate wirings P3 (fifth and sixth rows) are simultaneously operated.

For example, in a case where the top two gate wirings P1 (the first and second rows) are simultaneously operated, when a user touches a pixel region, a signal transmitted from a sensor unit in the touched pixel region moves along a corresponding data wiring. Here, since different types of sensor units (i.e., the first and second sensor units S_1 and S_2) are connected to each data wiring which extends in the vertical direction, that is, since two sensor units connected to one data wiring are different from each other, even if signals transmitted from the two different sensor units are mixed within the same data wiring, a voltage generated by the sensor unit in the touched pixel region can be accurately read. Thus, the coordinates of the position of the touched pixel region can be read without an error.

In the case of P1, a first sensor unit S_1 is formed at coordinates (1,1), and a second sensor unit S_2 is formed at coordinates (2,1) which are connected to the same data wiring as the coordinates (1,1). Likewise, a second sensor unit S_2 is formed at coordinates (1,2), and a first sensor unit S_1, which is different from the second sensor unit S_2 formed at the coordinates (1,2), is formed at coordinates (2,2). As for the other coordinates of P1, different sensor units (i.e., the first and second sensor units S_1 and S_2) are also formed at coordinates which are connected to the same data wiring. After P1, P2 and P3 are sequentially operated. In P2 and P3, different types of sensor units are also connected to one data wiring. Thus, the coordinates of a position at which a sensing voltage is generated can be accurately read without an error.

FIG. 5 is a diagram illustrating a case where the interlaced scan method is applied to the sensor array substrate according to the first exemplary embodiment of the present invention. As described above, the method (hG2D) of simultaneously driving two gate wirings is applied to the sensor array substrate according to the first exemplary embodiment. However, in the interlaced scan method, unlike in the progressive scan method, sensor units in the first and third rows I1 are simultaneously operated, and then sensor units in the second and fourth rows 12 are simultaneously operated. Finally, sensor units in the fifth and seventh rows 13 are simultaneously operated.

For example, in a case where the gate wirings I1 in the first and third rows are simultaneously operated, when a user touches a pixel region, a signal transmitted from a sensor unit in the touched pixel region moves along a corresponding data wiring. Here, since different types of sensor units are connected to each data wiring which extends in the vertical direction, that is, since two sensor units connected to one data wiring are different from each other, even if signals transmitted from the two different sensor units are mixed within the same data wiring, a voltage generated by the sensor unit in the touched pixel region can be accurately read. Thus, the coordinates of the position of the touched pixel region can be read without an error.

In the case of I1, a first sensor unit S_1 is formed at coordinates (1,1), and a second sensor unit S_2 is formed at coordinates (3,1) which are connected to the same data wiring as the coordinates (1,1). Likewise, a second sensor unit S_2 is formed at coordinates (1,2), and a first sensor unit S_1, which is different from the second sensor unit S_2 formed at the coordinates (1,2), is formed at coordinates (3,2). As for the other coordinates of I1, different sensor units (i.e., the first and second sensor units S_1 and S_2) are also formed in pixel regions which are connected to the same data wiring. After I1, I2 and I3 are sequentially operated. In I2 and I3, different types of sensor units are also connected to one data wiring. Thus, the coordinates of a position at which a sensing voltage is generated can be accurately read without an error.

As described above with reference to FIGS. 2 through 5, the pattern in which sensor units of the sensor array substrate according to the first exemplary embodiment are arranged allows both the progressive scan method and the interlaced scan method to be applied to the sensor array substrate. Thus, the coordinates of a position at which a sensing voltage is generated can be accurately read without an error.

Referring back to FIG. 1, if the color filter layers 91, 92, and 93 are formed on the display substrate 200 (see FIG. 6), the sensor array substrate may not include the color filter layers 91, 92, and 93. In this case, a region of the sensor array substrate which directly faces the color filter layers 91, 92, and 93 formed on the display substrate 200 (see FIG. 6) may be defined as a unit pixel region.

An overcoat layer 100 is formed on the color filter layers 91, 92, and 93 to planarize a step difference between them. The overcoat layer 100 may be made of a material having a relative dielectric constant of 3.0 to 3.5 in order to reduce parasitic capacitance between the first and second thin-film transistors TFT_1 and TFT_2, various wirings included in the first and second sensor units S_1 and S_2, and a common electrode 111. The overcoat layer 100 may be formed as an organic or inorganic layer. The overcoat layer 100 may be formed as an organic layer in view of planarization characteristics. In this case, the overcoat layer 100 may be made of a transparent organic material.

The common electrode 111 is formed on the overcoat layer 100. The common electrode 111 applies a common voltage to a liquid crystal layer 300 (see FIG. 6). The common electrode 111 may contain a transparent conductive material such as ITO, IZO, or ZnO.

A shield film 121 is formed on the common electrode 111. Here, the shield film 121 may overlap the first and second thin-film transistors TFT_1 and TFT_2 and the first and second sensor units S_1 and S_2. In addition, the shield film 121 may overlap the gate wirings (i.e., the gate line and the gate electrode 22), the data wirings (i.e., the data line, the source and drain electrodes 61 and 62, and the drain electrode extension portion 63), and the sensing wirings (i.e., the sensing line, the sensor source electrode 64 and the sensor drain electrode 65) and may extend parallel to them.

The shield film 121 prevents signal noise in the first and second thin-film transistors TFT_1 and TFT_2 or the first and second sensor units S_1 and S_2 as follows.

To drive a switching device (not shown) which is formed on the display substrate 200 (see FIG. 6) and is connected to each pixel electrode, a signal is transmitted to the switching device. In this case, an electronic wave may be generated, and the generated electronic wave may distort the common voltage of the common electrode 111. The distorted common voltage may cause the first and second sensor units S_1 and S_2 to have signal noise. Accordingly, the first and second sensor units S_1 and S_2 may malfunction. In addition, the display quality of a display device may deteriorate, and the long-term reliability of the first and second sensor units S_1 and S_2 may be adversely affected.

An electrical path may be included to discharge the generated electronic wave to the outside. The shield film 121 provides this electrical path. That is, the shield film 121 may be made of a conductive material. Here, the shield film 121 may not electrically float but may be connected to an external ground electrode. Thus, the shield film 121 may send the generated electronic wave to the external ground electrode, thereby removing the generating electronic wave. Accordingly, the shield film 121 can prevent the first and second thin-film transistors TF_1 and TFT_2 and the first and second sensor units S_1 and S_2 from having signal noise.

Furthermore, the shield film 121 may be made of a material having a lower resistance than that of the material of the common electrode 111 and may electrically contact the common electrode 111. Accordingly, a voltage drop resulting from the resistance of the common electrode 111 can be reduced.

Also, the shield film 121 can prevent light, which is emitted from the backlight unit, from entering the first and second sensor units S_1 and S_2. To this end, the shield film 121 may have an optical density of 4 or more. To secure an optical density of 4 or more, the shield film 121 may be formed to a thickness of 500 Å or greater.

The shield film 121 may be made of a conductive material. For example, the shield film 121 may contain at least one material selected from Al, Cr, Mo, Cu, Ni, W, Ta, and Ti or may contain a combination of these materials.

Hereinafter, a display device according to the first exemplary embodiment of the present invention will be described with reference to FIG. 6.

Referring to FIG. 6, the display device according to the first exemplary embodiment may include the sensor array substrate, the display substrate 200, and the liquid crystal layer 300. For the sake of simplicity, elements having the same functions as those illustrated in the drawings of the sensor array substrate according to the first exemplary embodiment are indicated by like reference numerals, and thus their description will be omitted.

The sensor array substrate may include the substrate 10, the first and second sensor units S_1 and S_2, the overcoat layer 100, which is formed on the first and second sensor units S_1 and S_2, and the shield film 121, which is formed on the overcoat layer 100. Here, each of the first and second sensor units S_1 and S_2 senses light and is formed in any one of a plurality of unit pixel regions defined on the substrate 10. The sensor array substrate further includes the common electrode 111 formed on the overcoat layer 100. The shield film 121 is formed on the common electrode 111.

The display substrate 200 faces the sensor array substrate and includes pixel electrodes (not shown). A switching device is connected to each pixel electrode and controls a voltage applied to each pixel electrode. A voltage applied to a pixel electrode and a voltage applied to the common electrode 111 drive liquid crystals of the liquid crystal layer 300, thereby adjusting the amount of light that passes through the liquid crystal layer 300.

The liquid crystal layer 300 is interposed between the sensor array substrate and the display substrate 200. The transmittance of light through the liquid crystal layer 300 is controlled by a voltage difference between the pixel electrodes and the common electrode 111.

Hereinafter, a method of manufacturing the sensor array substrate according to the first exemplary embodiment of the present invention will be described with reference to FIGS. 7 through 14.

First, referring to FIGS. 7 and 8, to form the light-blocking pattern 16 on the substrate 10, for example, a-Si is deposited on the whole surface of the substrate 10 by PECVD. Accordingly, an a-Si film is formed. Then, the a-Si film is patterned to form the light-blocking pattern 16. Here, the light-blocking pattern 16 may be formed on a region of the substrate 10 on which each of the first sensor units S_1 is to be formed.

Next, a conductive film for forming gate wirings and ground wirings is deposited and then patterned, thereby forming the gate line (not shown), the gate electrode 22, and the ground wiring 23. Here, the gate electrode 22 is formed on a region of the substrate 10 on which each of the first and second thin-film transistors TFT_1 and TFT_2 is to be formed. The ground wiring 23 is formed to contact the light-blocking pattern 16.

Next, the gate insulating film 30 is deposited on the substrate 10, the gate wirings, and the ground wiring 23 by PECVD or reactive sputtering. As a result, the gate insulating film 30 containing SiNx, SiOx, SiON, or SiOC may be formed.

Referring to FIG. 9, the semiconductor layer 42 is formed on the gate insulating film 30 to overlap the gate electrode 22. In addition, the first sensor semiconductor layer 44 is formed of, e.g., a-SiGe on the light-blocking pattern 16 to overlap the light-blocking pattern 16. Also, the second sensor semiconductor layer 46 is formed of, e.g., a-Si.

Next, the ohmic contact layer patterns 51 and 52 are formed on the semiconductor layer 42 and the first and second sensor semiconductor layers 44 and 46.

Thereafter, a conductive film for forming data wirings and sensing wirings is deposited on the ohmic contact layer patterns 51 and 52 and is then patterned, thereby forming the data wirings and the sensing wirings. Here, each data wiring includes the data line (not shown), the source electrode 61, the drain electrode 62, and the drain electrode extension portion 63, which extends from the drain electrode 62 and is connected to the sensor source electrode 64. In addition, each sensing wiring includes the sensor source electrode 64 and the sensor drain electrode 65.

Next, the passivation film 70 is formed by depositing an insulating material, such as SiNx or SiOx, using, e.g., PECVD.

Then, a via hole is formed by patterning the gate insulating film 30 and the passivation film 70. As a result, a portion of a top surface of the ground wiring 23 is exposed.

Referring to FIG. 10, a conductive film for forming sensor gate electrodes, first and second light-blocking films, and ground connection wirings is deposited by, e.g., sputtering and is then patterned, thereby forming the sensor gate electrode 84, the first and second light-blocking films 82 and 85, and the ground connection wiring 86.

Through the above processes, the first and second thin-film transistors TFT_1 and TFT_2 and the first and second sensor units S_1 and S_2 are formed (operation S1010).

Referring to FIG. 11, the color filter layers 91, 92, and 93 are formed on the passivation film 70, the sensor gate electrode 84, the ground connection wiring 86, and the first and second light-blocking films 82 and 85 by using any one of a printing method, which uses a material for forming color filter layers and an inkjet printing device, a gravure printing method, a screen printing method, and a photolithography method.

Referring to FIG. 12, an organic layer is stacked on the color filter layers 91, 92, and 93 by using, e.g., PECVD. As a result, the overcoat layer 100 is formed (operation S1020).

Referring to FIG. 13, ITO or IZO is deposited on the overcoat layer 100 by using, e.g., sputtering. As a result, the common electrode 111 is formed (operation S1030_1).

Referring to FIG. 14, the shield film 121 is formed of a metallic material on the common electrode 111 by using, e.g., sputtering (operation S1040_1).

Through the above processes, the sensor array substrate according to the first exemplary embodiment is formed.

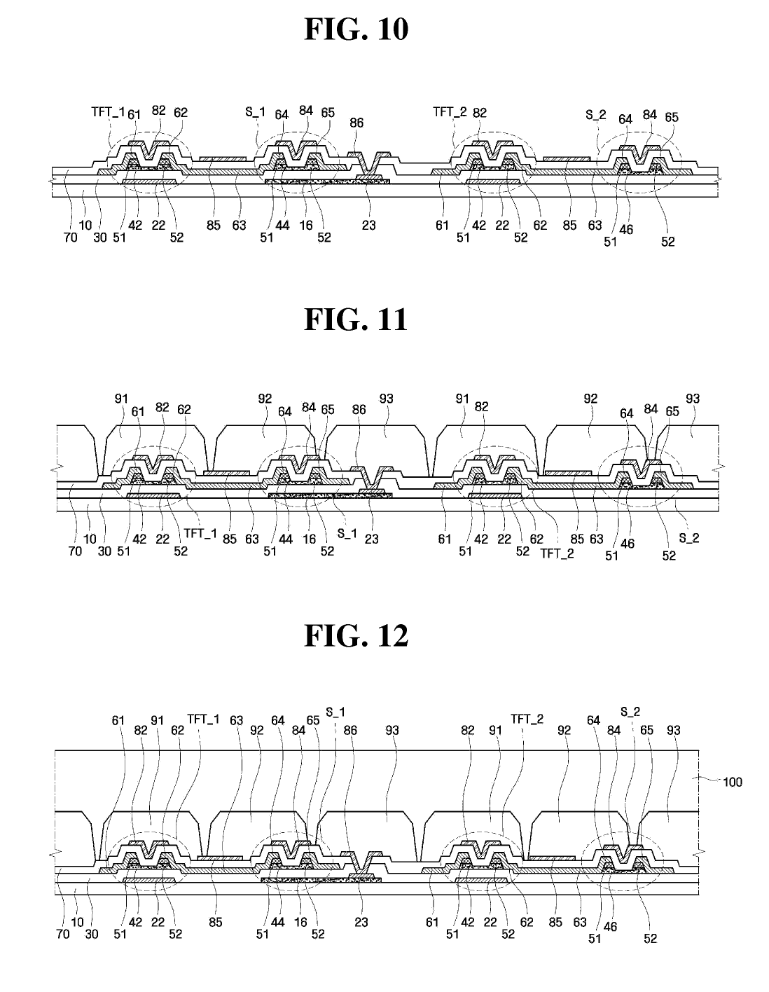

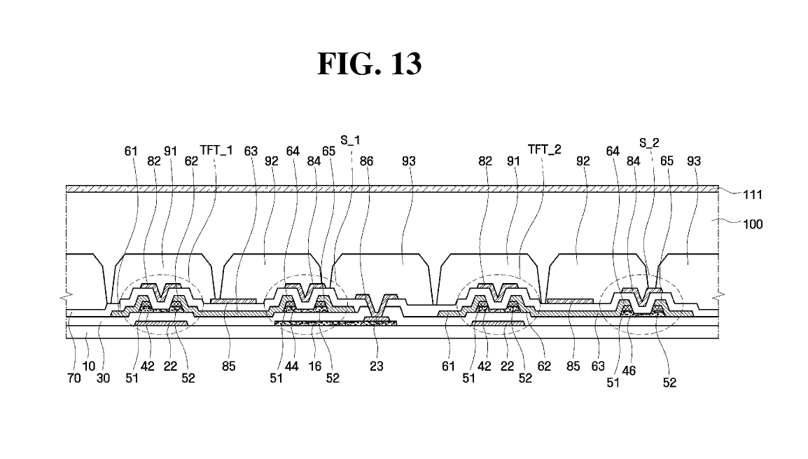

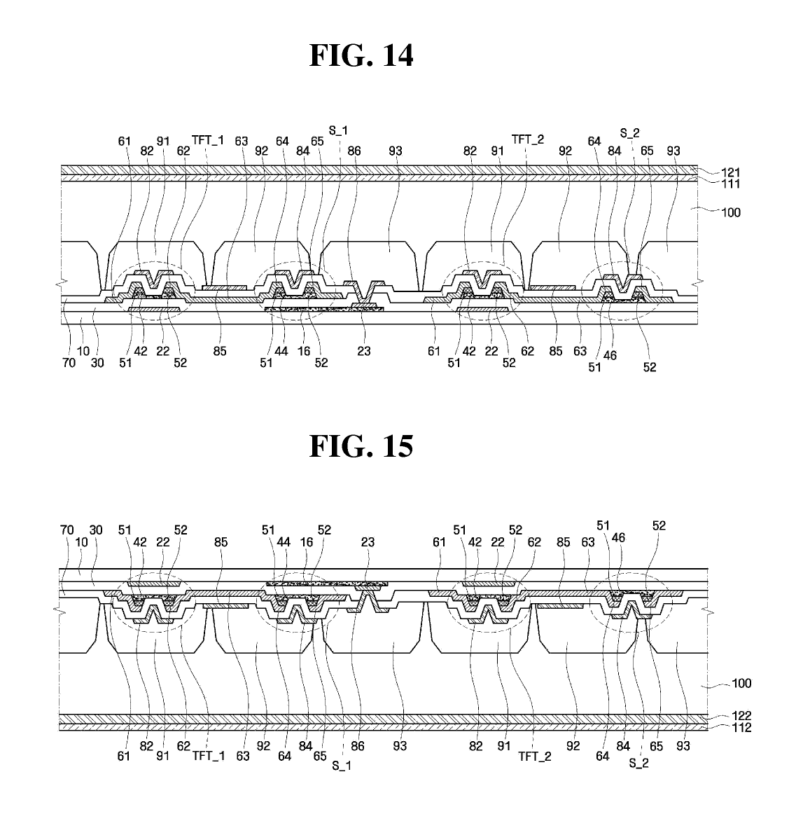

Hereinafter, a sensor array substrate, a display device including the same, and a method of manufacturing the sensor array substrate according to a second exemplary embodiment of the present invention will be described with reference to FIGS. 15 through 18.

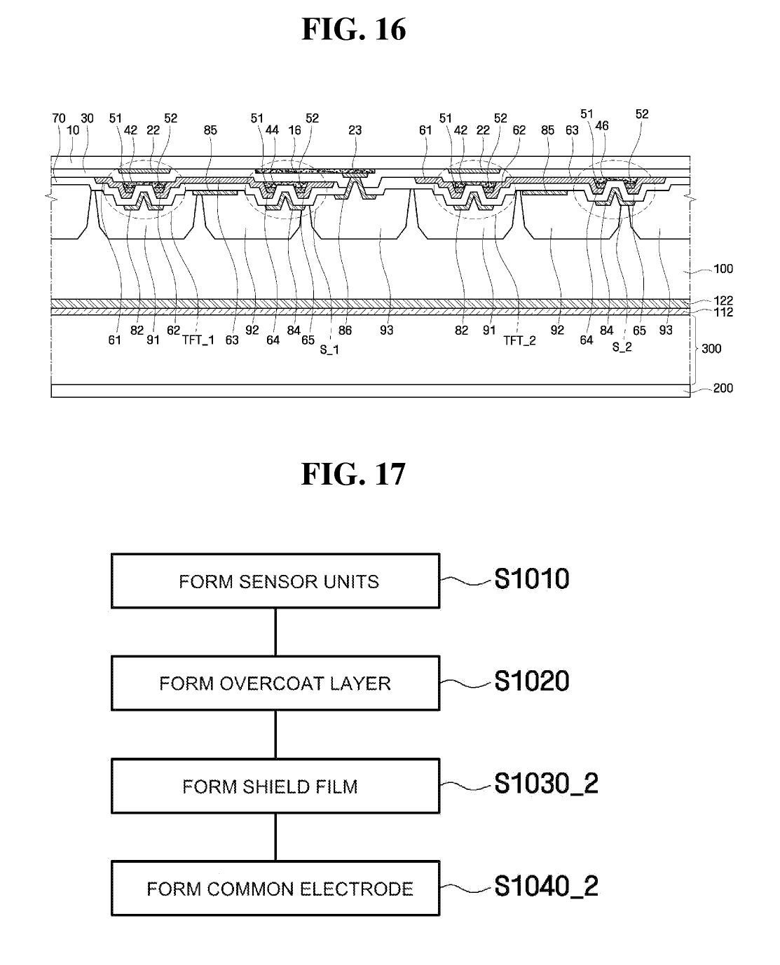

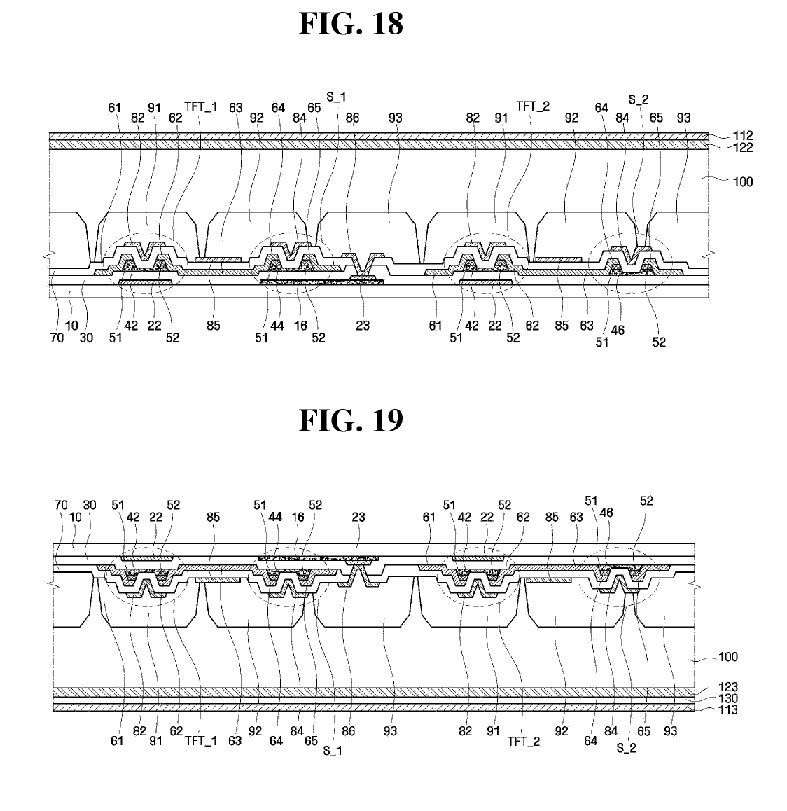

FIG. 15 is a cross-sectional view of a sensor array substrate according to a second exemplary embodiment of the present invention. FIG. 16 is a cross-sectional view of a display device according to the second exemplary embodiment of the present invention. FIG. 17 is a flowchart illustrating a method of manufacturing the sensor array substrate according to the second exemplary embodiment of the present invention. FIG. 18 is a cross-sectional view for explaining processes included in the method of manufacturing the sensor array substrate according to the second exemplary embodiment of the present invention. For the sake of simplicity, elements having the same functions as those illustrated in the drawings of the first exemplary embodiment are indicated by like reference numerals, and thus their description will be omitted.

The sensor array substrate, the display device including the same, and the method of manufacturing the sensor array substrate according to the second exemplary embodiment have basically the same structure as those according to the first exemplary embodiment except for the following features.

That is, referring to FIG. 15, a shied film 122 is interposed between an overcoat layer 100 and a common electrode 112.

In addition, referring to FIG. 16, in the sensor array substrate included in the display device according to the second exemplary embodiment, the shield film 122 is interposed between the overcoat layer 100 and the common electrode 112.

Referring to FIG. 17 and FIG. 18, the shield film 122 is formed of a metallic material on the overcoat layer 100 by using, e.g., sputtering (operation S1030_2). Then, ITO or IZO is deposited on the shield film 122 by, e.g., sputtering to form the common electrode 112 (operation S1040_2). As a result, the sensor array substrate according to the second exemplary embodiment of the present invention is completed.

Hereinafter, a sensor array substrate, a display device including the same, and a method of manufacturing the sensor array substrate according to a third exemplary embodiment of the present invention will be described with reference to FIGS. 19 through 22.

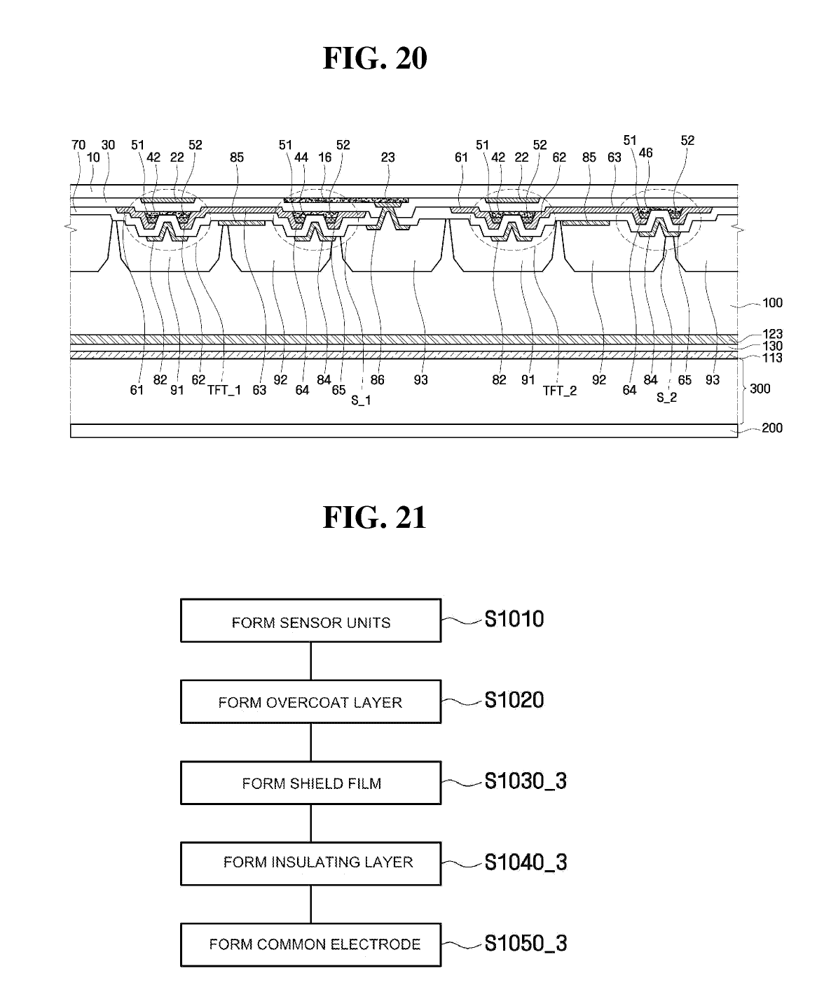

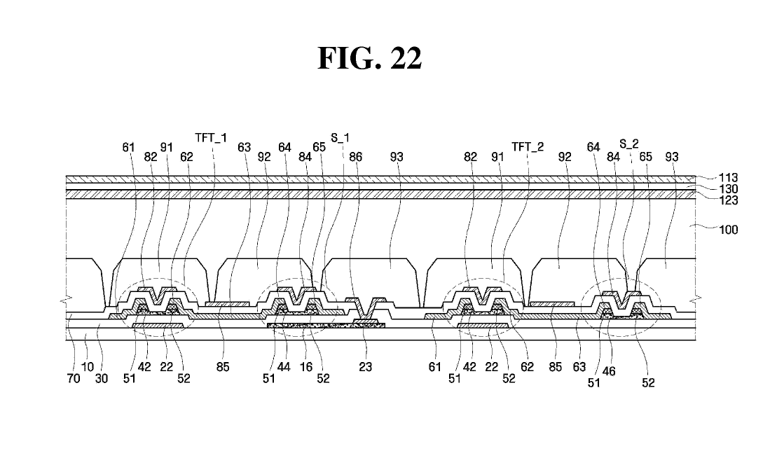

FIG. 19 is a cross-sectional view of a sensor array substrate according to a third exemplary embodiment of the present invention. FIG. 20 is a cross-sectional view of a display device according to the third exemplary embodiment of the present invention. FIG. 21 is a flowchart illustrating a method of manufacturing the sensor array substrate according to the third exemplary embodiment of the present invention. FIG. 22 is a cross-sectional view for explaining processes included in the method of manufacturing the sensor array substrate according to the third exemplary embodiment of the present invention. For the sake of simplicity, elements having the same functions as those illustrated in the drawings of the first exemplary embodiment are indicated by like reference numerals, and thus their description will be omitted.

The sensor array substrate, the display device including the same, and the method of manufacturing the sensor array substrate according to the third exemplary embodiment have basically the same structure as those according to the first exemplary embodiment except for the following features.

That is, referring to FIG. 19 and FIG. 20, a shield film 123 is formed on an overcoat layer 100, an insulating layer 130 is formed on the shield film 123, and a common electrode 113 is formed on the insulating layer 130. That is, the insulating layer 130 is interposed between the shield film 123 and the common electrode 113. Although not shown in the drawings, a via hole may be formed in the insulating layer 130 to electrically connect the shield film 123 to the common electrode 113.

Referring to FIG. 21 and FIG. 22, the shield film 123 is formed of a metallic material on the overcoat layer 100 by, e.g., sputtering (operation S1030_3).

Then, an organic or inorganic insulating layer is stacked on the shield film 123 by, e.g., PECVD. As a result, the insulating layer 130 is formed (operation S1040_3).

Next, a via hole (not shown), which exposes the shield film 123, is formed in the insulating layer 130 such that the shield film 123 may be electrically connected to the subsequently formed common electrode 113.

Then, ITO or IZO is deposited on the insulating layer 130 and the exposed shield film 123 by using, e.g., sputtering. Accordingly, the common electrode 113 is formed (operation S1050_3). As a result, the sensor array substrate according to the third exemplary embodiment of the present invention is completed.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A sensor array substrate, comprising:
a substrate;
a plurality of pixel regions defined by intersections of gate wirings and data wirings on the substrate; and
a plurality of first sensor units and a plurality of second sensor units disposed in the pixel regions,
wherein the first sensor units are configured to sense light in an infrared wavelength range, the second sensor units are configured to sense light in a visible wavelength range, two first sensor units disposed adjacent to each other in a data wiring direction form a first group, and two second sensor units disposed adjacent to each other in the data wiring direction form a second group, and
wherein the first group and the second group are alternately arranged in the data wiring direction and the first group and the second group are alternately arranged in a gate wiring direction.

2. The substrate of claim 1, further comprising an overcoat layer disposed on the first and second sensor units.

3. The substrate of claim 2, further comprising a color filter layer disposed between the first and second sensor units and the overcoat layer.

4. The substrate of claim 2, further comprising a shield film disposed on the overcoat layer, the shield film overlapping with the first and second sensor units.

5. The substrate of claim 4, further comprising a common electrode disposed on the overcoat layer, wherein the common electrode is disposed between the shield film and the overcoat layer.

6. The substrate of claim 4, further comprising a common electrode disposed on the overcoat layer, wherein the shied film is disposed between the common electrode and the overcoat layer.

7. The substrate of claim 1, wherein each of the first sensor units comprises a light-blocking pattern, a gate insulating film, and a sensor semiconductor layer sequentially disposed on the substrate, wherein the light-blocking pattern and the sensor semiconductor layer overlap each other.

8. The substrate of claim 1, wherein the first and second sensor units are configured to be operated by sequentially driving the gate wirings on a pair-by-pair basis, wherein two gate wirings in each pair are configured to be simultaneously driven.

9. The substrate of claim 8, wherein the two gate wirings which are configured to be driven simultaneously are adjacent to each other.

10. The substrate of claim 8, wherein a gate wiring which is not driven is interposed between the two gate wirings which are configured to be driven simultaneously.

11. A method of manufacturing a sensor array substrate, the method comprising:
forming gate wirings and data wirings on a substrate, the gate wirings and data wirings defining a plurality of pixel regions; and
forming a plurality of first sensor units and a plurality of second sensor units in the pixel regions,
wherein the first sensor units are configured to sense light in an infrared wavelength range, the second sensor units are configured to sense light in a visible wavelength range, two first sensor units disposed adjacent to each other in a data wiring direction form a first group, and two second sensor units disposed adjacent to each other in the data wiring direction form a second group, and
wherein the first group and the second group are alternately arranged in the data wiring direction and the first group and the second group are alternately arranged in a gate wiring direction.

12. The method of claim 11, further comprising forming an overcoat layer on the first and second sensor units.

13. The method of claim 12, further comprising forming a color filter layer on the first and second sensor units before the forming the overcoat layer.

14. The method of claim 12, further comprising forming a shield film on the overcoat layer, the shield film overlapping with the first and second sensor units.

15. The method of claim 14, further comprising forming a common electrode on the overcoat layer before forming the shield film, wherein the common electrode is disposed between the overcoat layer and the shield film.

16. The method of claim 14, further comprising forming a common electrode on the overcoat layer, wherein the shied film is disposed between the common electrode and the overcoat layer.

17. The method of claim 11, wherein forming the first sensor units comprises sequentially forming a light-blocking pattern, a gate insulating film, and a sensor semiconductor layer on the substrate, wherein the sensor semiconductor layer overlaps the light-blocking pattern.

18. A display device, comprising:
a sensor array substrate;
a display substrate facing the sensor array substrate and comprising pixel electrodes; and
a liquid crystal layer interposed between the sensor array substrate and the display substrate,
wherein the sensor array substrate comprises:
a substrate;
a plurality of pixel regions defined by intersections of gate wirings and data wirings on the substrate;
a plurality of first sensor units disposed in first pixel regions and configured to sense light in an infrared wavelength range; and
a plurality of second sensor units disposed in second pixel regions and configured to sense light in a visible wavelength range,
wherein two first sensor units disposed adjacent to each other in a data wiring direction form a first group, and two second sensor units disposed adjacent to each other in the data wiring direction form a second group, and
wherein the first group and the second group are alternately arranged in the data wiring direction and the first group and the second group are alternately arranged in a gate wiring direction.

19. The display device of claim 18, wherein the sensor array substrate further comprises an overcoat layer disposed on the first and second sensor units.

20. The display device of claim 19, wherein the sensor array substrate further comprises a color filter layer interposed between the first and second sensor units and the overcoat layer.

21. The display device of claim 19, wherein the sensor array substrate further comprises a shield film disposed on the overcoat layer, the shield film overlapping with the first and second sensor units.

22. The display device of claim 21, wherein the sensor array substrate further comprises a common electrode disposed on the overcoat layer, wherein the common electrode is disposed between the shield film and the overcoat layer.

23. The display device of claim 21, wherein the sensor array substrate further comprises a common electrode disposed on the overcoat layer, wherein the shied film is disposed between the common electrode and the overcoat layer.

24. The display device of claim 18, wherein each of the first sensor units of the sensor array substrate comprises a light-blocking pattern, a gate insulating film, and a sensor semiconductor layer sequentially disposed on the substrate, wherein the light-blocking pattern and the sensor semiconductor layer overlap each other.

25. The display device of claim 18, wherein the first and second sensor units of the sensor array substrate are configured to be operated by sequentially driving the gate wirings on a pair-by-pair basis, wherein two gate wirings in each pair are configured to be simultaneously driven.

26. The display device of claim 25, wherein the two gate wirings of the sensor array substrate which are configured to be driven simultaneously are adjacent to each other.

27. The display device of claim 25, wherein a gate wiring which is not driven is interposed between the two gate wirings of the sensor array substrate which are configured to be driven simultaneously.

28. A sensor array substrate, comprising:
a substrate;
gate lines disposed on the substrate;
data lines and sensing lines disposed on the substrate and extending in a direction crossing with the gate lines; and
a first column of sensor units comprising pairs of first sensor units and pairs of second sensor units alternately disposed between a first data line and a second data line,
wherein a first sensing line and a second sensing line are disposed between the first data line and the second data line, and the first sensor units are electrically connected to the first sensing line and the second sensor units are electrically connected to the second sensing line, and
wherein the first sensor units are electrically connected to the first data line and the second sensor units are electrically connected to the second data line.

29. The display device of claim 28, further comprising a second column of sensor units disposed adjacent to the first column of sensor units, the second column of sensor units comprising pairs of first sensor units and pairs of second sensor units alternately disposed between a third data line and a fourth data line,
wherein the first sensor units of the first column of sensor units are disposed adjacent to the second sensor units of the second column of sensor units in a row direction, and
wherein the second sensor units of the first column of sensor units are disposed adjacent to the first sensor units of the second column of sensor units in the row direction.
